(19) United States
(12) Patent Application Publication
(10) Pub. No.: US 2008/0057660 A1
(43) Pub. Date: Mar. 6, 2008

(54) Step-gate for a semiconductor device

(76) Inventors: Kuo-Chi Tu, Hsin-Chu (TW); Jai-Hoon Sim, Hsin-Chu City (TW); Chun-Yao Chen, Hsin-Chu (TW)

Correspondence Address: SLATER & MATSIL, L.L.P., 17950 PRESTON ROAD, SUITE 1000, DALLAS, TX, 75252, US

(21) Appl. No.: 11/511,977

(22) Filed: Aug. 29, 2006

(51) Int. Cl. H01L 21/20; H01L 21/8242

(52) U.S. Cl. 438/386; 438/253; 438/243; 438/396

(57) ABSTRACT

A semiconductor device using a recessed step gate. An embodiment comprises a recessed region in a portion of the substrate, a transistor with one source/drain region located within the recessed region and one source/drain region located out of the recessed region, a storage device connected to the source/drain located out of the recessed region, and a bit line connected to the source/drain located within the recessed region.

### TECHNICAL FIELD

The present invention relates generally to semiconductor devices, and more specifically to semiconductor devices having a step gate.

### BACKGROUND

The scaling down of the transistor and capacitor of a Dynamic Random Access Memory (DRAM) cell is a constant effort in order to increase the packing density and improve the DRAM's overall performance. However, as the transistor in the cell is reduced in size, the standard channel length of the transistor (the width of the gate) is also reduced. A shorter channel length leads to more pronounced short-channel effects and greater subthreshold leakage of the cell's transistor, and ultimately degrades the performance of the cell.

Several approaches have been proposed to overcome these limitations. One such approach used to suppress the short-channel effects and the subthreshold leakage is to heavily dope the substrate. Unfortunately, heavy doping of the substrate also forms a high electric field near the source-node junction of the cell. This high electric field degrades the data retention time of the DRAM cell, which also works to degrade the overall performance of the DRAM cell.

Another approach is described in “Enhancement of Data Retention Time in DRAM using Step Gated Asymmetric (STAR) Cell Transistors,” Jang, R&D Division, Hynix Semiconductor, Inc. In this approach, illustrated in FIG. 1, raised step gates 103 are formed on a substrate 101 to extend the channel length of the pass gate transistors 105. These step gates are formed by etching areas 106 that will eventually be connected to the capacitors 111, but not etching the area 109 that will eventually connect to the bit line 113. However, etching the areas 106 of the substrate that will be connected to the storage capacitors 111 may damage the substrate during the process. This damage may cause leakage from the storage capacitors 111 and will reduce the data retention time of the overall cell.

FIG. 2 illustrates another approach, the Recessed Channel Array Transistor (RCAT), in which the gates 203 of the transistors 205 are recessed into the substrate 201. This approach is described in “The Breakthrough in data retention time of DRAM using Recess-Channel-Array Transistor (RCAT) for 88 nm feature size and beyond” Kim et al, Semiconductor R&D Division, Samsung Electronic Co. However, as the size of transistors is reduced, the process for forming a recessed gate into a reduced substrate creates new processing difficulties. Also, by using this process, the body effects of the transistor are increased and the capacitance of the transistor is increased, which would cause a decrease in the switching speed of the transistor.

Another approach is to form a planar gate transistor with an asymmetric junction profile as described by Shiho et al., in U.S. Pat. No. 6,238,967. In this approach the electrode to the capacitor is doped to a shallow level, while the electrode to the bit line is doped to a much greater concentration and depth. Unfortunately, as the size of transistors is reduced, this approach cannot effectively minimize the short channel effects and the sub-threshold leakage current, even in very low doping concentrations.

Because of these and other problems associated with the current methods of forming DRAM cells, a new step-gate transistor that improves data retention time is needed.

### SUMMARY OF THE INVENTION

These and other problems are generally solved or circumvented, and technical advantages are generally achieved, by preferred embodiments of the present invention that allow for a reduction in the width of the transistor, but with an increase in channel length, while preventing damage to the source/node connection.

One aspect of the present invention involves a method of manufacturing a semiconductor device comprising that begins by providing a substrate. Within this substrate a recessed region and a non-recessed region are formed. A transistor is formed on the substrate so that one source/drain region is located within the recessed region and another source/drain region is located outside of the recessed region. Finally, a bit line is electrically coupled to the first source/drain region (in the recessed region) and a storage device is connected to the second source/drain region (out of the recessed region).

Another aspect of the present invention involved a method of manufacturing a DRAM that also begins with providing a substrate and forming a recessed region in the substrate. A transistor is formed with one source/drain region located in the recessed region and one source/drain located out of the recessed region. A bit line is electrically coupled to the first source/drain region (within the recessed region) and a capacitor is electrically coupled to the second source/drain region (out of the recessed region).

Yet another embodiment of the present invention involves a method of manufacturing a DRAM comprised of providing a similar substrate and forming a recessed region. In this embodiment two transistors are formed, with each transistor utilizing the same source/drain region located within the recessed region of the substrate, and separate source/drain regions located out of the recessed region. A bit line is connected to the shared source/drain region within the recessed region and separate capacitors are connected to each of the source/drain regions located out of the recessed region.

By using these configurations in semiconductor devices and DRAM cells that have a step gate for the bit line node, the short-channel effects are reduced by creating a longer channel length for the same width, without corresponding damage done to the connection of the storage device. These all work to improve the data retention of the cell while allowing for an overall reduction in cell size.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 is a cross-sectional view of a DRAM cell with a substrate that is raised to form a step gate in the prior art;

FIG. 2 is a cross-sectional view of a section of a substrate wherein the gate is recessed into the substrate in the prior art; and

FIGS. 3A-3L are cross-sectional views of a wafer after various process steps are performed in accordance with an embodiment of the present invention.

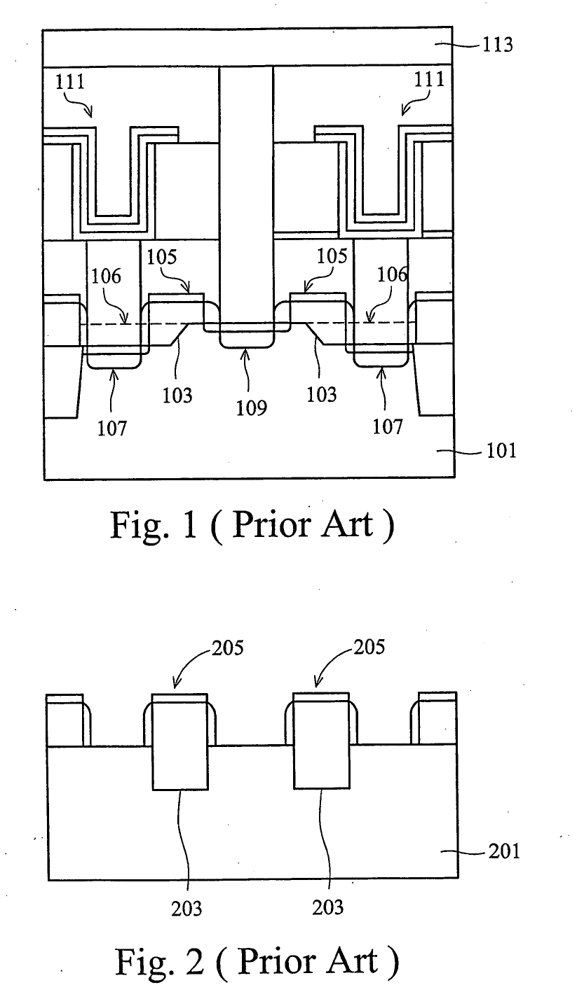

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to steps in manufacturing the preferred embodiments in a specific context, namely a DRAM cell with a recessed region to form a bit line connection to a step-gate transistor. The invention may also be applied, however, to making other semiconductor devices.

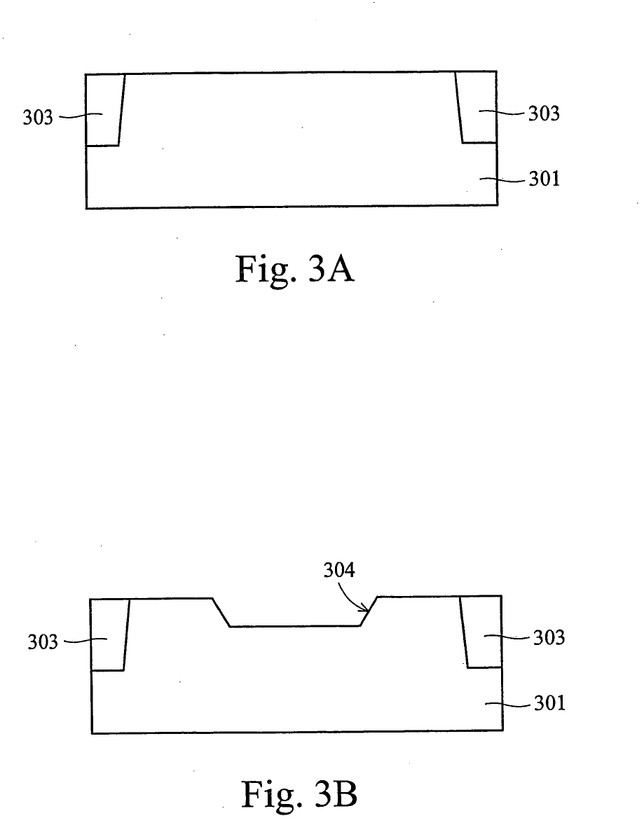

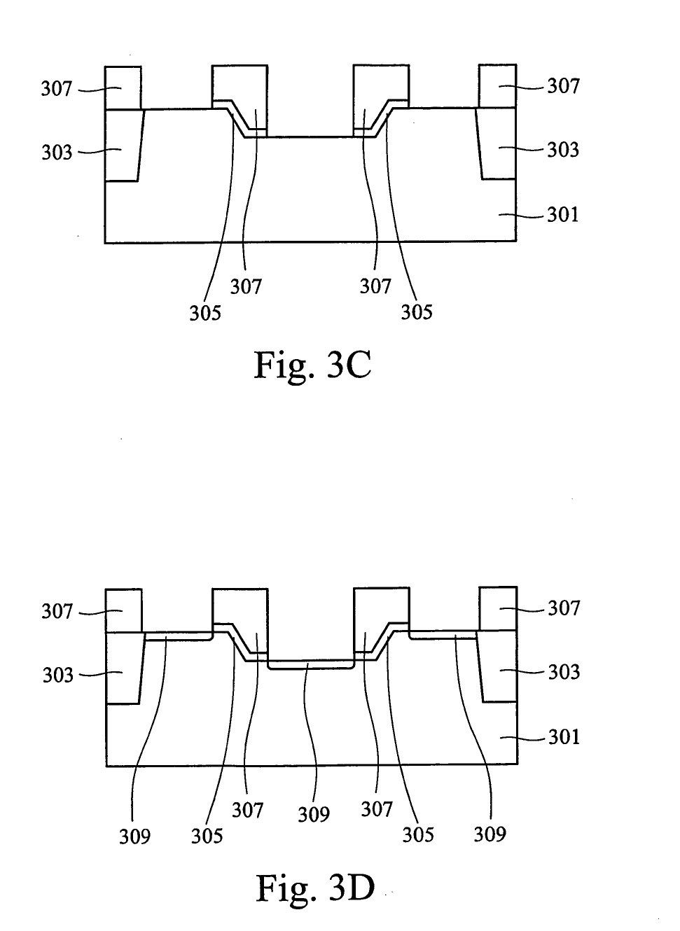

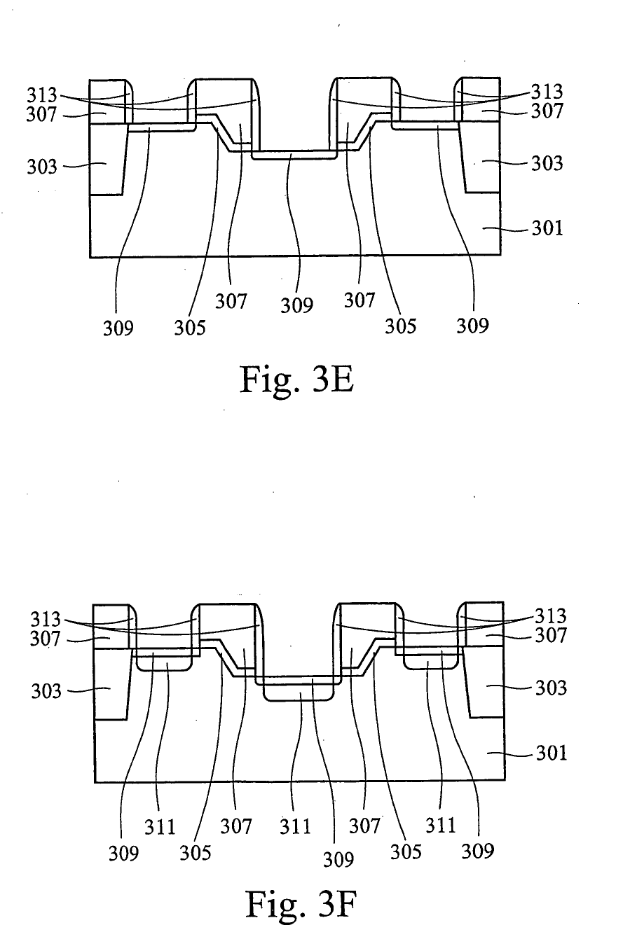

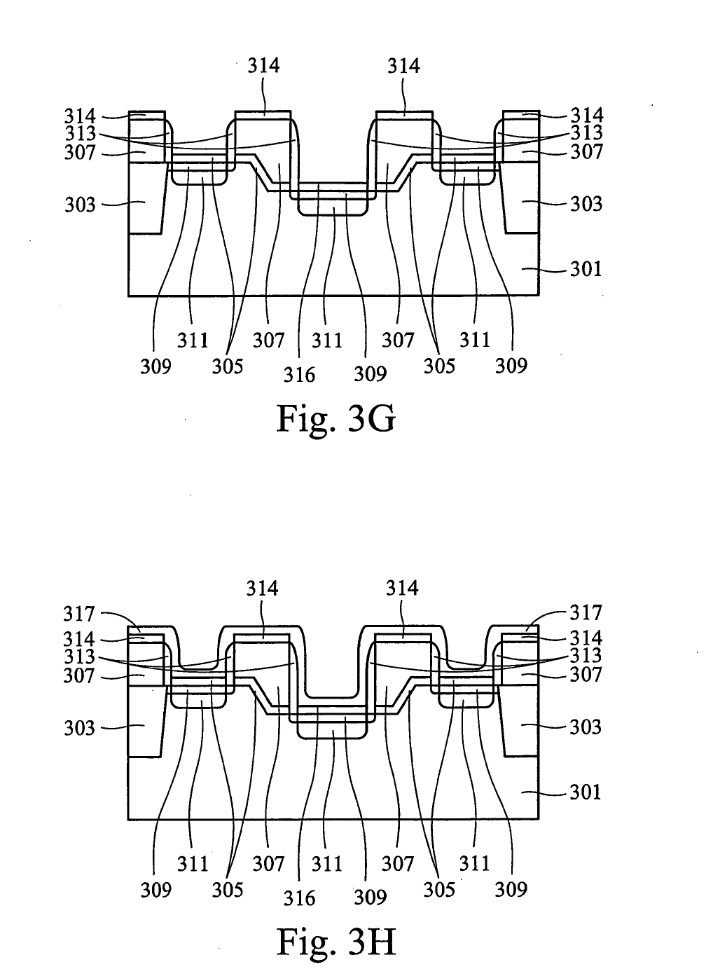

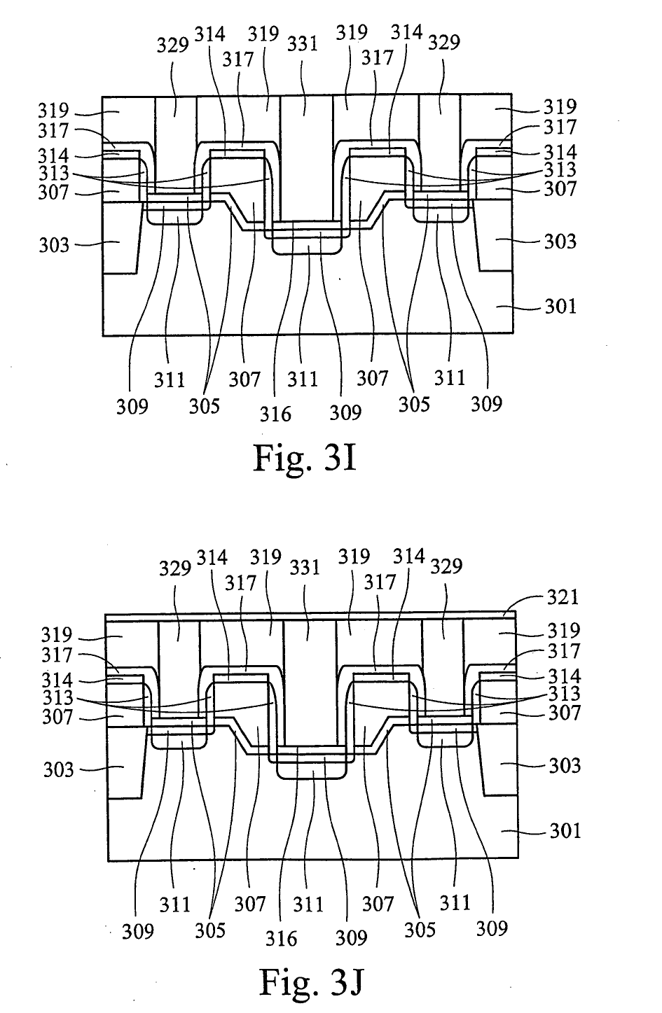

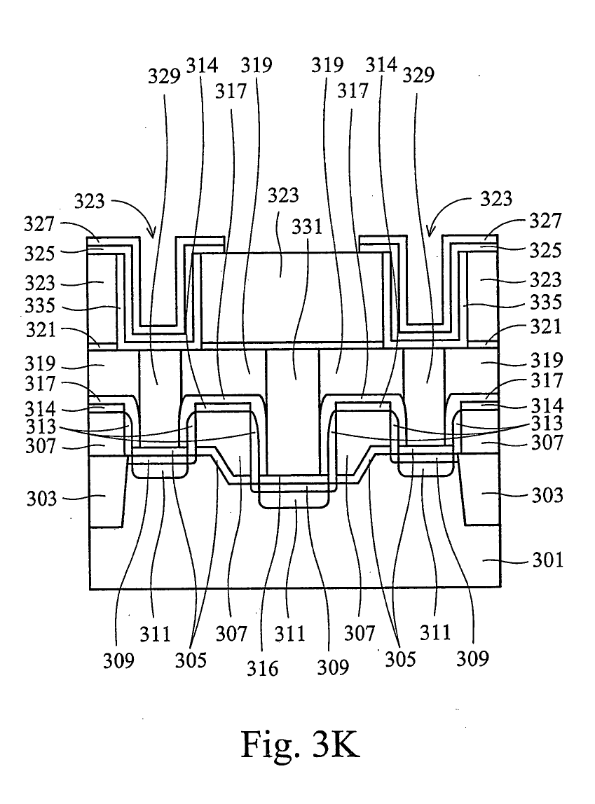

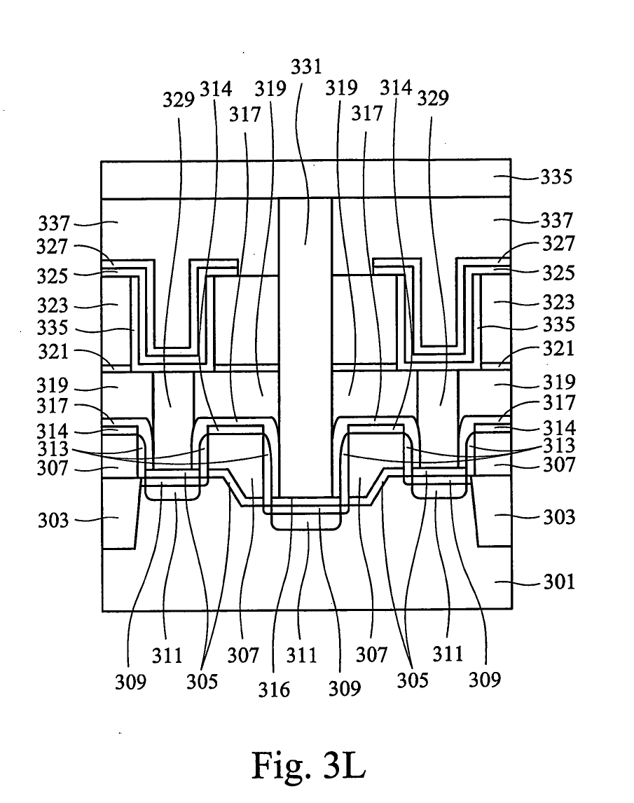

FIG. 3A illustrates a substrate 301 with shallow trench isolations (STIs) 303 formed therein. The substrate 301 may comprise bulk silicon, doped or undoped, or an active layer of a silicon on insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

The STIs 303 are generally formed by etching the substrate 301 to form a trench and filling the trench with a dielectric material as is known in the art. Preferably, the STIs 303 are filled with a dielectric material such as an oxide material, a high-density plasma (HDP) oxide, or the like, formed by conventional methods known in the art.

FIG. 3B illustrates the resulting structure after a recessed region 304 has been formed in the substrate 301. This recessed region 304 may be formed by placing a masking layer pattern on the substrate 301 and etching the recessed region 304 to the desired depth, as is known in the art. In an embodiment, the recessed region 304 has a depth of between about 150 Å to about 2,000 Å, with the depth preferably being about 500 Å.

FIG. 3C illustrates the formation of the gate dielectrics 305 and gate electrodes 307 These gate dielectrics 305 and gate electrodes 307 may be formed and patterned on the substrate 301 by any suitable process known in the art. The gate dielectrics 305 are formed partially within the recessed region 304 and partially without the recessed region 304. This has the effect of increasing the channel length of the transistor, without a corresponding increase in the width of the gate dielectric 305.

The gate dielectrics 305 are preferably a high-K dielectric material, such as silicon oxide, silicon oxynitride, silicon nitride, an oxide, a nitrogen-containing oxide, a combination thereof, or the like. Preferably, the gate dielectrics 305 have a relative permittivity value greater than about 4. Other examples of such materials include aluminum oxide, lanthanum oxide, hafnium oxide, zirconium oxide, hafnium oxynitride, or combinations thereof.

In the preferred embodiment in which the gate dielectric layers 305 comprise an oxide layer, the gate dielectric layers 305 may be formed by any oxidation process, such as wet or dry thermal oxidation in an ambient comprising an oxide, H₂O, NO, or a combination thereof, or by chemical vapor deposition (CVD) techniques using tetra-ethyl-ortho-silicate (TEOS) and oxygen as a precursor. In an embodiment, the gate dielectric layers 305 are between about 8 Å to about 50 Å in thickness, but preferably about 16 Å in thickness.

The gate electrodes 307 preferably comprise a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, or a combination thereof. In one example, amorphous silicon is deposited and recrystallized to create poly-crystalline silicon (poly-silicon). In the preferred embodiment in which the gate electrodes are poly-silicon, the gate electrode 307 may be formed by depositing doped or undoped poly-silicon by low-pressure chemical vapor deposition (LPCVD) to a thickness in the range of about 400 Å to about 2,500 Å, but more preferably about 1,500 Å.

FIG. 3D illustrates the result after lightly doping the substrate 301. Lightly doped drain/source (LDD) regions 309 are formed in the substrate 301, preferably by implanting appropriate impurities, such as arsenic ions or BF₂ ions, using the gate electrode 307 as a mask. These LDD regions 309 may be formed such that the device is either an NMOS device or a PMOS device. Because the gate electrode is used as a mask, the LDD regions 309 are substantially aligned with the edges of the gate electrodes 307. As is known in the art, by adjusting the implanting energy level and impurity elements, impurities can be implanted to desired depths.

FIG. 3E illustrates the formation of spacers 313 along the sidewalls of the gate dielectrics 305 and gate electrodes 307. To form the spacers 313, a spacer layer is typically blanket deposited on the previously formed structure. The spacer layer preferably comprises SiN, oxynitride, SiC, SiON, oxide, and the like and is preferably formed by commonly used methods such as chemical vapor deposition (CVD), plasma enhanced CVD, sputter, and other methods known in the art. The spacers 313 are then patterned, preferably by anisotropically etching and removing the spacer layer from the horizontal surfaces of the structure.

FIG. 3F illustrates the implantation of the source/drain regions 311. In the preferred embodiment, the source/drain regions 311 are formed by implanting appropriate impurities, such as arsenic or boron, into the substrate 301, using the spacers 313 as masks. The source/drain regions 311 may be formed such that the device is either an NMOS device or a PMOS device. Because the spacers 313 are used as masks, the source/drain regions 311 are substantially aligned with the respective spacers 313.

It should be noted that, though the above-described process describes a specific process, one of ordinary skill in the art will realize that many other processes, steps, or the like may be used. For example, one of ordinary skill in the art will realize that a plurality of implants may be performed using various combinations of spacers and liners to form source/drain region having a specific shape or characteristic suitable for a particular purpose. Any of these processes may be used to form the source/drain regions 311, and the above description is not meant to limit the present invention to the steps presented above.

FIG. 3G illustrates the resulting structure after an optional salicide process has been used to form a silicide contact for the bit line 316, silicide contacts for the source/node regions 315, and silicide contacts for the gates 314. The silicide contacts for the bit line 316, source/node 315, and gate 314 preferably comprise nickel. However, other commonly used metals, such as titanium, cobalt, palladium, platinum, erbium, and the like, can also be used. As is known in the art, the silicidation is preferably performed by blanket deposition of an appropriate metal layer, followed by an annealing step in which the metal reacts with the underlying exposed silicon. Un-reacted metal is then removed, preferably with a selective etch process. The thickness of the silicide contact for the bit line 316, the source/nodes 315, and the gates 314 are preferably between about 5 nm and about 50 nm.

FIG. 3H illustrates the formation of an optional first contact etch stop layer 317 over the structure. Preferably, contact etch stop layer 317 has a thickness of between about 300 Å and about 1,500 Å. The contact etch stop layer 317 can be made from materials such as nitride, oxynitride, oxide, SiC, SiON, combinations thereof, or the like.

FIG. 3I illustrates the deposition and patterning of a first inter-level dielectric layer 319. Preferably, the first inter-level dielectric layer 319 comprises an oxide that may be formed by chemical vapor deposition (CVD) techniques using tetra-ethyl-ortho-silicate (TEOS) and oxygen as a precursor. However, other methods and materials known in the art may be used. Preferably, the first inter-level dielectric layer 319 is about 4,000 Å to about 13,000 Å in thickness, but other thicknesses may be used. The surface of the first inter-level dielectric layer 319 may be planarized, preferably by a CMP process using an oxide slurry.

After the first inter-level dielectric layer 319 has been formed, vias 329 and 331 are formed and connected to the previously formed silicide contacts for the source/nodes 315 and bit line 316, respectively. These vias 329 and 331 can be formed through a damascene process, whereby masks are deposited onto the surface of the inter-level dielectric layer 319, holes are etched into the surface, and conductive material (such as copper) is used to fill the holes. It should be noted that the vias 329 ad 331 may comprise one or more layers of conductive material. For example, the vias 329 and 331 may include barrier layers, adhesive layers, multiple conductive layers, or the like.

FIG. 3J illustrates the formation of a second contact etch stop layer 321 over the inter-level dielectric layer 319. Preferably, the second contact etch stop layer 321 has a thickness of between about 300 Å and about 1,500 Å. The contact etch stop layer 321 can be made from materials such as SiN or SiON, although other materials known in the art, such as SiC or oxide, could also be used.

FIG. 3K illustrates the structure after the deposition and patterning of a second inter-level dielectric layer 323 and the formation of capacitors 333. Preferably, the second inter-level dielectric layer 323 comprises an oxide that may be formed either by chemical vapor deposition (CVD) techniques using tetra-ethyl-ortho-silicate (TEOS) and oxygen as a precursor, or else by plasma enhanced chemical vapor deposition (PECVD). However, other methods and materials known in the art may be used. Preferably, the second inter-level dielectric layer 323 is about 4,000 Å to about 13,000 Å in thickness, but other thicknesses may be used. The surface of the second inter-level dielectric layer 323 may be planarized, preferably by a CMP process using an oxide slurry.

In an embodiment, the capacitors 333 are Metal Insulator Metal (MIM) capacitors comprising a bottom electrode 335, a dielectric layer 325, and a top electrode 327. The bottom electrodes 335 are preferably formed by depositing and patterning a layer of conductive material, preferably TiN, TaN, ruthenium, or the like. The bottom electrode 335 may be formed, for example, by CVD techniques and is preferably about 100 Å to about 500 Å in thickness, but more preferably about 200 Å in thickness. After the bottom electrode 335 is formed, the excess conductive material on the surface of the second inter-level dielectric layer 323 is removed by, for example, a CMP process or an etch back process.

The dielectric layers 325 and the top electrodes 327 are preferably formed by depositing and patterning a dielectric layer and a conductive layer, respectively. The dielectric layers 325 are preferably a high-K dielectric film, such as Ta₂O₅, Al₂O₃, ZrO₂, HFO₂, BST, PZT, an oxide, other multi-layer high-K dielectric, or the like. The dielectric layers 325 are preferably formed by CVD techniques and are preferably about 15 Å to about 200 Å in thickness, but more preferably about 110 Å in thickness.

The top electrodes 327 are preferably a conductive material such as TiN, TaN, ruthenium, aluminum, tungsten, copper, or the like, and may be formed, for example, by CVD. The top electrodes 327 are preferably about 100 Å to about 500 Å in thickness, but more preferably about 110 Å in thickness. It should be noted that other types, shapes, or the like of capacitors may be used.

FIG. 3L illustrates the structure after the deposition and patterning of a third inter-level dielectric layer 337. Preferably, the third inter-level dielectric layer 337 comprises an oxide that may be formed by chemical vapor deposition (CVD) techniques using tetra-ethyl-ortho-silicate (TEOS) and oxygen as a precursor. However, other methods and materials known in the art may be used. Preferably, the third inter-level dielectric layer 337 is about 4,000 Å to about 13,000 Å in thickness, but other thicknesses may be used. The surface of the third inter-level dielectric layer 337 may be planarized, preferably by a CMP process using an oxide slurry.

After the third inter-level dielectric layer 337 has been formed, via 331 is extended through the second inter-level dielectric layer 323 and the third inter-level dielectric layer 337. The via 331 can be formed using a damascene process, whereby masks are deposited onto the surface of the inter-level dielectric layer 337, holes are etched into the surface, and conductive material (such as copper) is used to fill the holes. However, other methods and materials that are known in the art could also be used to extend this via 331. It should be noted that the via 331 may comprise one or more layers of conductive material. For example, the via 331 may include barrier layers, adhesive layers, multiple conductive layers, or the like.

FIG. 3L also illustrates the formation of a bit line 335. This bit line 335 is electrically coupled with the via 331 to connect to the silicide contact for the bit line 316. It is prefereably formed by a damascene process, whereby masks are deposited onto the surface of the inter-level dielectric layer 337, a pattern is etched into the surface, and conductive material is used to fill the pattern. Other methods or materials that are known in the art could also be used to form this bit line 335.

As one of ordinary skill in the art will appreciate, in the present invention the region of the substrate in contact with the storage capacitor remains unetched, and less damage is done to the substrate in this region. With less damage the leakage rate of the capacitor is reduced, and the overall cell will realize an increase in its retention time.

Although the present invention and its advantages have been described in detail, it should be understood that various changes, substitutions and alterations can be made herein without departing from the spirit and scope of the invention as defined by the appended claims. For example, there are multiple methods for the deposition of material as the structure is being formed. Any of these deposition methods that achieve substantially the same result as the corresponding embodiments described herein may be utilized according to the present invention.

Moreover, the scope of the present application is not intended to be limited to the particular embodiments of the methods described in the specification. As one of ordinary skill in the art will readily appreciate from the disclosure of the present invention, methods presently existing, or later to be developed, that perform substantially the same, function or achieve substantially the same result as the corresponding embodiments described herein may be utilized according to the present invention. Accordingly, the appended claims are intended to include within their scope such methods.

What is claimed is:

1. A method of manufacturing a semiconductor device, the method comprising:
providing a substrate;
forming a recessed region and a non-recessed region in the substrate, the recessed region having a first side and a second side on opposite sides of the recessed region;
forming a first transistor on the substrate along the first side of the recessed region, the first transistor having a first source/drain region and a second source/drain region, the first source/drain region being located in the recessed region and the second source/drain region being located in the non-recessed region;
forming a bit line electrically coupled to the first source/drain region; and
forming a first storage device electrically coupled to the second source/drain region.

2. The method of claim 1, wherein the recessed region has a depth of about 150 Å to about 2,000 Å.

3. The method of claim 1, wherein the first storage device is a capacitor.

4. The method of claim 3, wherein the capacitor is a Metal-Insulator-Metal capacitor comprising:
a top electrode;
an insulating layer; and
a bottom electrode.

5. The method of claim 4, wherein the top electrode and bottom electrode comprise tantalum nitride or titanium nitride.

6. The method of claim 1, further comprising forming a second transistor on the substrate along the second side of the recessed region, the second transistor sharing the same first source/drain region as the first transistor and having a third source/drain region, the third source/drain region being located in the non-recessed region.

7. The method of claim 6, further comprising forming a second storage device electrically coupled to the third source/drain region.

8. The method of claim 7, wherein the second storage device is a capacitor.

9. A method of manufacturing a DRAM, the method comprising:
providing a substrate;
forming a recessed region in the substrate;
forming a first transistor, the first transistor having a first source/drain region, a second source/drain region, and a gate electrode, the first source/drain region located in the recessed region of the substrate, the second source/drain region located in a non-recessed region of the substrate, and the gate electrode interposed between the first and second source/drain region;
forming a bit line electrically coupled to the first source/drain region; and
forming a first capacitor electrically coupled to the second source/drain region, at least a portion of the first capacitor being positioned above the second source/drain region.

10. The method of claim 9, wherein the recessed region has a depth of about 150 Å to about 2,000 Å.

11. The method of claim 9, further comprising forming a second transistor on the substrate, the second transistor sharing the same first source/drain region as the first transistor and having a third source/drain region being located in the non-recessed region of the substrate.

12. The method of claim 11, further comprising forming a second capacitor electrically coupled to the third source/drain region, at least a portion of the second capacitor being positioned above the third source/drain region.

13. The method of claim 9, wherein the first capacitor is a Metal-Insulator-Metal capacitor comprising:
a top electrode;
an insulating layer; and
a bottom electrode.

14. The method of claim 13, wherein the top electrode and bottom electrode are tantalum nitride or titanium nitride.

15. The method of claim 13, wherein the insulating layer comprises Al₂O₃, Ta₂O₅, or ZrO₂.

16. A method of manufacturing a DRAM, the method comprising:
providing a substrate;
forming a recessed region and a non-recessed region in the substrate, the recessed region having a first sidewall and a second sidewall on opposite sides of the recessed region forming a first transistor along the first sidewall, the first transistor having a first source/drain region and a second source/drain region, the first source/drain region located in the recessed region and the second source/drain region located in the non-recessed region;
forming a second transistor along the second sidewall, the second transistor having the same first source/drain region as the first transistor, and the second transistor having a third source/drain located in the non-recessed region;
forming a bit line electrically coupled to the first source/drain region;
forming a first capacitor electrically coupled to the second source/drain region; and
forming a second capacitor electrically coupled to the third source/drain region.

17. The method of claim 16, wherein the recessed region has a depth of about 150 Å to about 2,000 Å.

18. The method of claim 16, wherein the first and second capacitors are Metal-Insulator-Metal capacitors comprising:
a top electrode;
an insulating layer; and
a bottom electrode.

19. The method of claim 18, wherein the top electrode and bottom electrodes comprise tantalum nitride or titanium nitride.

20. The method of claim 18, wherein the insulating layers comprise Al₂O₃, Ta₂O₅, or ZrO₂.
